(19) United States
(12) Patent Application Publication
(10) Pub. No.: US 2013/0336346 A1
(43) Pub. Date: Dec. 19, 2013

(54) OPTICAL COUPLING TECHNIQUES AND CONFIGURATIONS BETWEEN DIES

(71) Applicants: Mauro J. Kobrinsky, Portland, OR (US); Jia-Hung Tseng, Portland, OR (US); Bruce A. Block, Portland, OR (US)

(72) Inventors: Mauro J. Kobrinsky, Portland, OR (US); Jia-Hung Tseng, Portland, OR (US); Bruce A. Block, Portland, OR (US)

(21) Appl. No.: 13/997,635

(22) PCT Filed: Mar. 5, 2012
(86) PCT No.: PCT/US12/27793

§ 371 Date: Jun. 24, 2013

(51) Int. Cl. H01L 31/16; H01S 5/026; H01L 33/58

(52) U.S. Cl. CPC H01L 31/16; H01L 33/58; H01S 5/026; H01S 5/0262
USPC 372/26; 257/98; 257/80; 438/31; 438/24; 372/50.21

(57) ABSTRACT

Embodiments of the present disclosure provide optical connection techniques and configurations. In one embodiment, an opto-electronic assembly includes a first semiconductor die including a light source to generate light, and a first mode expander structure comprising a first optical material disposed on a surface of the first semiconductor die, the first optical material being optically transparent at a wavelength of the light, and a second semiconductor die including a second mode expander structure comprising a second optical material disposed on a surface of the second semiconductor die, the second material being optically transparent at the wavelength of the light, wherein the second optical material is evanescently coupled with the first optical material to receive the light from the first optical material. Other embodiments may be described and/or claimed.

### FIELD

Embodiments of the present disclosure generally relate to the field of integrated circuits, and more particularly, to optical connection techniques and configurations between dies.

### BACKGROUND

Optical signals may be used to communicate information between integrated circuits (ICs) such as ICs formed on different dies. Present techniques to optically couple different dies may be incompatible with high volume manufacturing processes. For example, optical features of different dies may presently be aligned and coupled using active alignment techniques where a light signal is routed between the dies while fabrication equipment positions the dies relative to one another until precise alignment is achieved to provide maximum coupling (e.g., maximum light intensity, minimum coupling loss, etc.).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a top view of an example optical interconnect system, in accordance with some embodiments.

FIGS. 2A-2B schematically illustrate a side view of an optical coupling technique and configuration, in accordance with some embodiments.

FIG. 3 schematically illustrates another side view of the optical coupling technique and configuration of FIG. 2B, in accordance with some embodiments.

FIG. 4 schematically illustrates a top perspective view of the optical coupling technique and configuration of FIG. 3, in accordance with some embodiments.

FIGS. 5A-5B schematically illustrate a side view of another optical coupling technique and configuration, in accordance with some embodiments.

FIG. 6 schematically illustrates a top perspective view of the optical coupling technique and configuration of FIG. 5B, in accordance with some embodiments.

FIG. 7 is a flow diagram for a method of fabricating an opto-electronic assembly, in accordance with some embodiments.

FIG. 8 schematically illustrates an example system that may be part of an optical interconnect system described herein in accordance with some embodiments.

### DETAILED DESCRIPTION

Embodiments of the present disclosure provide optical coupling techniques and configurations between dies of an opto-electronic assembly. In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations are described as multiple discrete operations in turn, in a manner that is most helpful in understanding the claimed subject matter. However, the order of description should not be construed as to imply that these operations are necessarily order dependent. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, front/back, over/under, side, horizontal and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous. The term “coupled” may refer to a direct connection, an indirect connection, or an indirect communication.

As used herein, the term “module” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

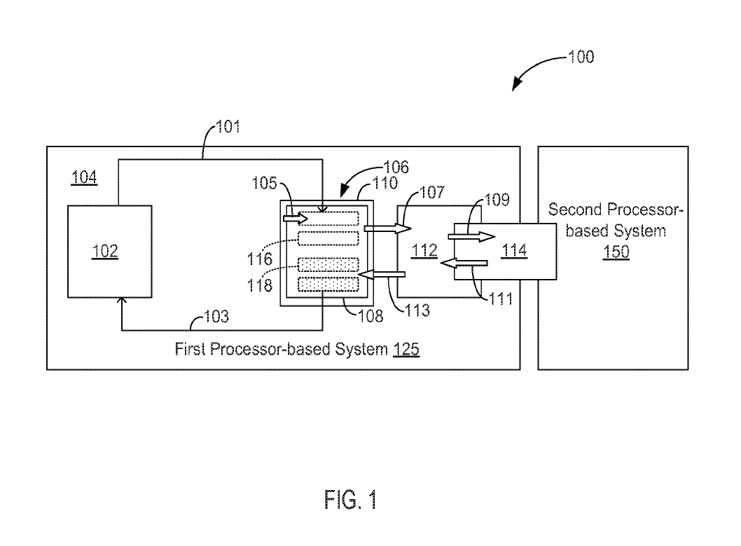

FIG. 1 schematically illustrates a top view of an example optical interconnect system 100, in accordance with some embodiments. The optical interconnect system 100 may include a first processor-based system 125 and a second processor-based system 150 coupled together using a system-level optical coupler 114 such as, for example, fiber(s) and/or waveguide(s) to route light in the form of “optical mode” signals (e.g., light 109, 111) between the first processor-based system 125 and the second processor-based system 150.

The first processor-based system 125 may include a processor 102 mounted on a substrate 104, which may be referred to as a “package substrate.”

The processor 102 may be operatively coupled with an opto-electronic assembly 106 that is configured to convert electrical signals such as, for example, electrical input/output (I/O) signals of the processor 102 into corresponding optical signals (e.g., light 107) for routing of the optical signals to another device configured to receive the optical signals (e.g., second processor-based system 150). The opto-electronic assembly 106 may be further configured to receive and convert optical signals into electrical signals.

According to various embodiments, the techniques and configurations described herein may be used to optically couple two dies together to allow routing of optical signals (e.g., light) between the two dies. For example, in some embodiments, the opto-electronic assembly 106 may include two dies optically coupled together according to techniques and configurations described herein. For example, in the depicted embodiment, the opto-electronic assembly 106 includes a second die 110 mounted on the substrate 104 and a first die 108 optically coupled with the second die 110. The second die 110 may be, for example, a photonic die comprising a planar lightwave circuit (PLC) and/or optical components such one or more modulators (e.g., modulator 116), detectors (e.g., detector 118). The photonic die may further include splitters, gratings, and the like (not shown). The first die 108 may be a light-source die, which may be referred to as a “laser die” in some embodiments, and may include a light source to generate light for optical signaling. The light-source die can be any type of chip suitable for producing optical signals. The light-source die may include an array of lasers. In some embodiments, the light-source die may be a photonic die comprising a PLC and/or optical components such one or more modulators (e.g., modulator 116), detectors (e.g., detector 118), splitters, gratings, and the like.

The modulator 116 and the detector 118 are depicted in dashed form to indicate that they are disposed under the first die 108 in the illustrated embodiment. In other embodiments, the first die 108 may be mounted on the substrate 104 and the second die 110 may be optically coupled with the first die 108. Although the second die 110 is depicted as larger than the first die 108 in FIG. 1 for the sake of clarity, the dies 108, 110 may have different relative sizes in other embodiments. In some embodiments, the die of the first die 108 or second die 110 that includes the light source is optically coupled with the connector element 112 and/or the system-level optical coupler 114. The connector element 112 may be mounted on the die having the light source.

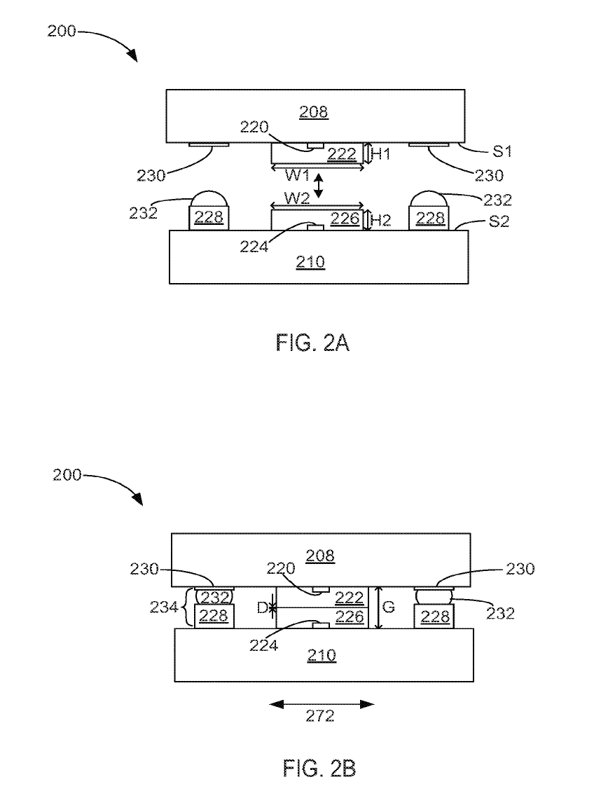

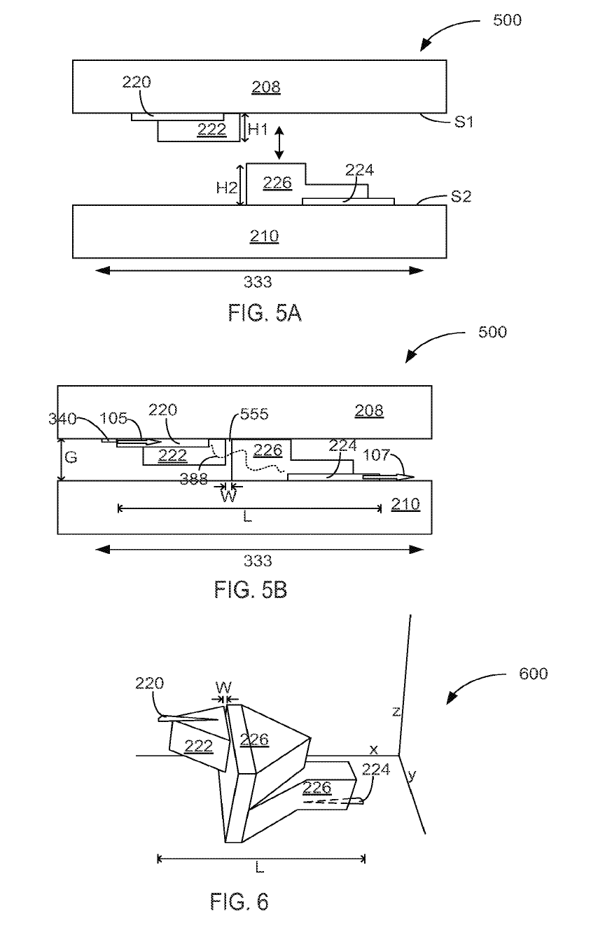

The opto-electronic assembly 106 may be mounted on the substrate 104 in some embodiments. In other embodiments, the opto-electronic assembly 106 may be mounted on the processor 102 or components of the opto-electronic assembly 106 may be formed as part of the processor 102. According to various embodiments, the opto-electronic assembly 106 may comport with other embodiments described herein (e.g., opto-electronic assembly 200 of FIG. 2B or opto-electronic assembly 500 of FIG. 5B).

In some embodiments, the processor 102 may be configured to drive (e.g., indicated by arrow 101) one or more modulator devices (e.g., modulator 116) of the opto-electronic assembly 106. The modulator 116 may include, for example, a waveguide configured to modulate light 105 received from the first die 108. The light 107 may be output from the modulator 116 to a connector element 112. The connector element 112 may include, for example, an optical plug or other coupler that further routes the light 109 from the opto-electronic assembly 106 over the system-level optical coupler 114 to the second processor-based system 150.

In some embodiments, the second processor-based system 150 is configured to send light 111 over the system-level optical coupler 114 to the first processor-based system 125. Although not shown, the second processor-based system 150 may be similarly equipped as the first processor-based system 125 or otherwise comport with embodiments described in connection the first processor-based system 125. The light 111 sent by the second processor-based system 150 may be received by the connector element 112 of the first processor-based system 125. The connector element 112 may route the light 113 to one or more detectors (e.g., detector 118) of the opto-electronic assembly 106. The processor 102 may be configured to process electrical signals (e.g., indicated by arrow 103) generated by the opto-electronic assembly 106 based on the light 113 received at the detector 118.

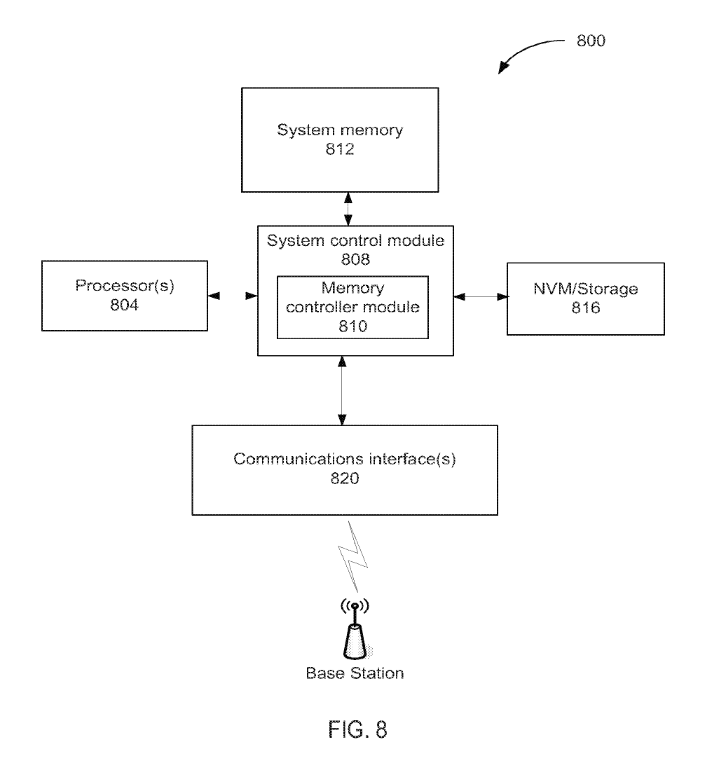

The first processor-based system 125 and/or the second processor-based system 150 may include additional components in some embodiments. For example, the first processor-based system 125 and/or the second processor-based system 150 may comport with embodiments described in connection with the example system 800 of FIG. 8. In other embodiments, techniques and configurations described herein to optically couple two dies together can be used in other systems that benefit from the principles described herein such as, for example, optical cables, optical links, optical sensors, network hubs, routers, optical backplanes, intra-chip optical links and the like.

FIGS. 2A-2B schematically illustrate a side view of an optical coupling technique and configuration, in accordance with some embodiments. In some embodiments, an opto-electronic assembly 200 is fabricated by optically and electrically coupling two dies together. In FIG. 2A, the opto-electronic assembly 200 is depicted prior to electrically and optically coupling a first semiconductor die (hereinafter “first die 208”) with a second semiconductor die (hereinafter “second die 210”). In FIG. 2B, the opto-electronic assembly 200 is depicted subsequent to electrically and optically coupling the first die 208 and the second die 210.

The first die 208 and/or the second die 210 may be composed of a semiconductor material such as, for example, silicon (Si) or a group III-V semiconductor material such as, for example, gallium arsenide (GaAs) or indium phosphide (InP). In eon embodiment, the second die 210 is composed of Si and the first die 208 is composed of a group III-V semiconductor material. The first die 208 and/or the second die 210 may include other suitable materials in other embodiments. In some embodiments, the first die 208 may comport with embodiments described in connection with first die 108 of FIG. 1 and the second die 210 may comport with embodiments described in connection with second die 110 of FIG. 1.

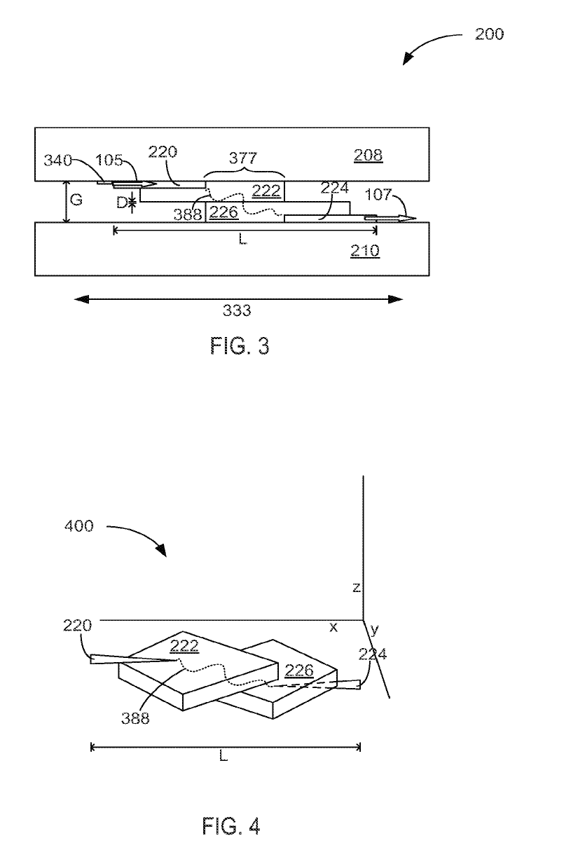

The first die 208 may include a first waveguide 220 on a surface, S1, of the first die 208, as can be seen. The second die 210 may include a second waveguide 224 on a surface S2 of the second die 210, as can be seen. The first waveguide 220 and/or the second waveguide 224 may include fin structures that are configured to route light in a direction along an elongate dimension of the fin structures (e.g., arrow 333 of FIG. 3 indicating a direction of the elongate dimension of the first waveguide 220 and the second waveguide 224). In the embodiment depicted in FIGS. 2A-2B, the elongate dimension of the first waveguide 220 and the second waveguide 224 extends in and out of the page. The first waveguide 220 and/or the second waveguide 224 may be configured to route single mode or multi-mode optical signals. According to various embodiments, the first die 208 and/or the second die 210 may include multiple waveguides on the respective surfaces S1 and S2 that are similarly configured as the first waveguide 220 and the second waveguide 224. In some embodiments, the waveguides 220, 224 may be disposed around and adjacent to a peripheral edge of the dies 208, 210.

The first waveguide 220 and/or the second waveguide 224 may include, for example, waveguide structures composed of a semiconductor material such as, for example, silicon (Si). The first waveguide 220 and/or the second waveguide 224 may be passive waveguide structures in some embodiments. In some embodiments, the first waveguide 220 and/or the second waveguide 224 may be composed of silicon nitride (SiN). Other materials may be used to fabricate the first waveguide 220 and/or the second waveguide 224 in other embodiments. In some embodiments, the opto-electronic assembly 200 may not include the first waveguide 220 or the first waveguide 220 may be replaced by the light source (e.g., light source 340 of FIG. 3). The light source 340 may direct light into the first optical material 222. In some embodiments, the optical materials of the first waveguide 220 and/or the second waveguide 224 may have an index of refraction ranging from 1.5 to 3.5. The optical materials of the waveguides 220, 224 may have other values for index of refraction in other embodiments.

In some embodiments, a first optical material 222 is disposed on the first waveguide 220 and the surface S1 of the first die 208 and a second optical material 226 is disposed on the second waveguide 224 and the surface S2 of the second die 210, as can be seen. The first and/or second optical material 222, 226 may be composed of a material that is optically transparent at a wavelength of light to be routed through the first and/or second waveguides 220, 224. In some embodiments, the first and/or second optical material 222, 226 may have an index of refraction from 1.5 to 2.

The first and/or second optical material 222, 226 may be configured to serve as mode expander structures for light being routed between the first waveguide 220 and the second waveguide 224. That is, the first optical material 222 and the second optical material 226, and their dimensions (e.g., heights H1, H2 and widths W1, W2) may be configured to allow evanescent coupling of the first waveguide 220 with the second waveguide 224 through the first optical material 222 and the second optical material 226. For example, the first optical material 222 and the second optical material 226 may provide an optical pathway for the light via an evanescent field such as a Gaussian intensity distribution of the light from the first waveguide 220 to the second waveguide 224. Evanescent coupling may include transmission of electromagnetic waves from one medium to another by means of an evanescent, exponentially decaying electromagnetic field. Evanescent coupling configurations are further described in connection with FIGS. 3-4.

The first optical material 222 may have a height, H1, relative to the surface S1 of the first die 208 and the second optical material 226 may have a height, H2, relative to the surface S2 of the second die 210. The heights H1 and H2 may be configured to allow evanescent coupling between the waveguides 220, 224 through the optical materials 222, 226 when the dies 208, 210 are coupled together (e.g., as shown in FIG. 2B).

Referring to FIGS. 2A and 2B, in some embodiments, the first optical material 222 and the second optical material 226, in combination, may serve as a mechanical stop to define a gap distance, G, between the first die 208 and the second die 210. The gap distance, G, may be calculated or closely approximated by adding heights H1 and H2 in some embodiments. According to various embodiments, the gap distance G may have a value between 4 and 10 microns. In one embodiment, the gap distance G has a value less than or equal to 8 microns. In some embodiments, the heights H1 and H2 have the same value. In other embodiments, the heights H1 and H2 may have different values.

In some embodiments, structures composed of optical materials 222, 226 may be formed on the respective dies 208, 210 without the waveguides 220 and 224 in order to provide additional mechanical stop capability.

The first optical material 222 may have a width, W1, and the second optical material may have a width, W2, as can be seen. In some embodiments, the widths W1, W2 may have a value between 8 and 12 microns. In one embodiment, the widths W1, W2 may have a value less than or equal to 10 microns. The widths W1, W2 may have different values or the same value according to various embodiments. The optical materials 222, 226 may have other dimensions in other embodiments including tapered profiles as depicted in FIGS. 4 and 6.

The optical materials 222, 226 may have mechanical properties suitable for serving as a mechanical stop as described herein. The mechanical properties may be selected to provide sufficient optical coupling between the optical materials 222, 226 to allow the light to travel between the waveguides 220, 224. For example, the mechanical properties may accommodate height (e.g., H1, H2) variations of the optical materials 222, 226 across regions where the optical materials 222, 226 overlap (e.g., region 377 of FIG. 3). The height variations may result, for example, from process variation in depositing or forming the optical materials 222, 226 or die rotations of the dies 208, 210 during assembly. In the regions where the optical materials 222, 226 overlap, a distance, D, between the optical materials 222, 226 of less than 100 nanometers (nm) may be achieved to ensure sufficient optical coupling between the optical materials 222, 226. In one embodiment, the distance D may represent a maximum distance between adjacent surfaces of the optical materials 222, 226 in the region 377 of FIG. 3.

In some embodiments, the mechanical properties of the optical materials 222, 226 are selected to provide sufficient mechanical compliance to accommodate height variations of the optical materials 222, 226 due to manufacturing variability, which may vary in the range of about 1 to 100 nm, or more. The mechanical properties that provide sufficient mechanical compliance may include, for example, materials that can deform under typical assembly forces (e.g., ranging from 0.1 to 50 newtons (N)) without cracking or manifesting other structural defects that adversely affect that structural integrity of the optical materials 222, 226. In one embodiment, the optical materials 222, 226 include a polymer having a Young's modulus in the range of 200 to 500 megapascals (MPa) at the attach temperature, which may typically range from 250-260° C., but may be as low as 150° C. or as high as 300° C. or higher. Materials with other values of Young's modulus can be used, since the deformation of the optical materials 222, 226 during the attach process can be increased by increasing the attach force or decreasing the total area of contact (e.g., in region 377 of FIG. 3) of the optical materials 222, 226 between the dies 208, 210. The trade offs described above may be approximated using the equation Δh=P*h/(E*A), where (Δh) represents height variations (e.g., of heights H1, H2) that can be accommodated, P represents a total attach force to couple the dies 208, 210, h represents a combined height (e.g., H1+H2) of the optical materials 222, 226, E represents the Young's modulus of the optical materials 222, 226, and A represents a total area of contact of the optical materials 222, 2226 between the dies 208, 210.

According to various embodiments, the optical materials 222, 224 may include wafer permanent resist (WPR), perfluorocyclobutyl (PFCB), PIMEL AM-210L, and the like. The optical materials 222, 224 may include other suitable materials in other embodiments.

According to various embodiments, the first optical material 222 and the second optical material 226 may further function as “collapse controller” structures by defining a gap distance, G, that further allows passive alignment between the dies 208, 210 and, thus, between corresponding waveguides 220, 224 during a solder reflow process that bonds dies 208, 210 together using a plurality of solder interconnect structures (hereinafter “interconnect structures 234”). Thus, the optical materials 222, 226 may function as collapse controllers and mode expander structures according to various embodiments.

For example, FIG. 2A may represent an opto-electronic assembly 200 before a solder reflow process bonds the dies 208, 210. The dies 208, 210 may be positioned relative to one another using fabrication equipment such that a surface of the first optical material 222 that is substantially parallel with the surface S1 of the first die 208 is opposite to a surface of the second optical material 226 that is substantially parallel with the surface S2 of the second die 210, as can be seen. The dies 208, 210 may further be positioned relative to one another such that corresponding interconnect structures on the different dies 208, 210 are aligned to couple together. For example, bumps 228 and solderable material 232 may be positioned opposite to pads 230 configured to bond with the solderable material 232. According to various embodiments, the waveguides 220, 224 and optical materials 222, 226 that form an optical pathway between the dies 208, 210 may be disposed between at least two of the interconnect structures 234, as can be seen.

Other configurations for the interconnect structures may be used in other embodiments. For example, the pad 230 may be formed on the second die 210 and the bump 228 may be formed on the first die 208 or the solderable material 232 may be disposed on an interconnect structure of the first die 208. For another example, the interconnect structures 234 may include more or fewer components than depicted in other embodiments.

In FIG. 2B, surfaces of the optical materials 222,226 may be brought together to define the gap distance G and heat may be applied as part of a solder reflow process that softens the solderable material 232. Solder self-alignment techniques may be used to provide passive alignment of the waveguides 220, 224 as the solderable material 232 cools and hardens such that a mechanical and electrical bond is formed between the passively aligned dies 208, 210 using the interconnect structures 234. Materials for the optical materials 222, 226 may be selected to resist softening at temperatures associated with solder reflow processes. In one embodiment, the optical materials 222, 226 may resist softening at temperatures up to at least 260° C. In other embodiments, low temperature solders with melting temperatures in the range of about 150-260° C. may be used (e.g. In—Sn solders).

The positioning and/or passive alignment of the dies 208, 210 as described in connection with FIGS. 2A-2B may provide less than 3 microns of misalignment of the first waveguide 220 relative to the second waveguide 224 in a direction (e.g., indicated by arrow 272) that is substantially perpendicular to an elongate dimension of the first waveguide and the second waveguide, in order to provide efficient optical coupling between the waveguides 220, 224. Less than 3 microns of misalignment between the waveguides 220, 224 in the described direction may provide less than 2-3 decibels (dB) of coupling loss, in some embodiments.

Subsequent to the solder reflow process, surfaces of the optical materials 222, 226 may be in direct contact or may be separated by a distance equal to or less than distance, D. In some embodiments, distance D is 100 nm or less to ensure sufficient optical coupling in some embodiments. Accordingly, a solder reflow process may simultaneously provide passive alignment of the dies 208, 210 (and waveguides 220, 224) relative to one another, provide electrical and mechanical coupling of the dies 208, 210 through the interconnect structures 234, and provide optical coupling (e.g., evanescent coupling) between the waveguides 220, 224.

FIG. 3 schematically illustrates another side view of the optical coupling technique and configuration of FIG. 2B, in accordance with some embodiments. FIG. 3 may depict a cross-section side view of the opto-electronic assembly 200 that is substantially perpendicular to the side view of FIG. 2B (e.g., arrow 333 of FIG. 3 may be perpendicular to arrow 272 of FIG. 2).

The first waveguide 220, the first optical material 222, the second optical material 226, and the second waveguide 224 may form an optical pathway between the first die 208 and the second die 210. In some embodiments, the first optical material 222 may be configured to cover only a portion of the first waveguide 220 and the second optical material 226 may be configured to cover only a portion of the second waveguide 224, as can be seen.

In some embodiments, the first die 108 may include a light source 340 configured to generate light 105. For example, the light source 340 may generate the light 105 based on electrical signals received through the interconnect structures 234 of FIG. 2B. In some embodiments, the light source 340 may be a laser or other light-emitting device fabricated on the die (e.g., the second die 208). The light 105 may be received by the first waveguide 220. In some embodiments, the light 105 may be received by the first waveguide 220 in a region of the first waveguide 220 that is not covered by the first optical material 222. The light 105 may be routed through the first waveguide 220 in the direction of the arrow of light 105 and enter the first optical material 222 and the second optical material 226, as can be seen.

The first optical material 222 and the second optical material 226 may serve as mode expanders in the region 377 where the optical materials 222, 226 overlap or are in intimate/direct contact with one another. The intimate/direct contact may include physical coupling at distances equal to or less than distance D, which may be about 100 nm in some embodiments. In some embodiments, an output portion of first waveguide 220 is disposed at a horizontal boundary or adjacent to the region 377 and an input portion of the second waveguide 224 is disposed at another horizontal boundary or adjacent to the region 377, as can be seen. The light 105 may propagate (e.g., intensity illustrated by 388) through the first optical material 222 and the second optical material 226, which are evanescently coupled in the region 377. The light 105 may be received at the second waveguide 224 and routed in the direction of the arrow of light 107 out of the second waveguide 224. The second optical material 226 may be configured to cover only a portion of the second waveguide 224, as can be seen. Light 105 and 107 (and intensity illustrated by 388) may represent the same light at a respective input and output of the optical pathway (e.g., optical pathway 400 of FIG. 4).

The optical pathway may have a length, L, of about 1.5 millimeters (mm) or less, in some embodiments. The length, L, may extend in a direction (e.g., indicated by arrow 333) that is parallel with an elongate dimension of the waveguides 220, 224. The optical pathway may have other dimensions in other embodiments.

FIG. 4 schematically illustrates a top perspective view of the optical coupling technique and configuration of FIG. 3, in accordance with some embodiments. An optical pathway 400 is depicted on a three-coordinate axis where the x-axis is parallel with the arrow 333 of FIG. 3, the y-axis is parallel with the arrow 272 of FIG. 2B, and the z-axis is perpendicular to a plane defined by the x-axis and the y-axis. The dies 208, 210 are not depicted for the sake of clarity.

The optical pathway 400 includes the first waveguide 220, the first optical material 222, the second optical material 226, and the second waveguide 224, optically coupled as shown to route light (e.g., light 105 of FIG. 3) across an optical interface (e.g., evanescent coupling, intensity illustrated by 388) of the optical materials 222, 226 of the light. A portion of the second waveguide 224 is depicted in dashed form to indicate that the portion underlies the second optical material 226. In some embodiments, the waveguides 220, 224 and optical materials 222, 226 may have a tapered profile, as can be seen, to facilitate the routing of light through the optical pathway 400. The waveguides 220, 224 and optical materials 222, 226 may have other configurations and/or profiles in other embodiments.

FIGS. 5A-5B schematically illustrate a side view of another optical coupling technique and configuration, in accordance with some embodiments. FIG. 5A may represent an opto-electronic assembly 500 prior to coupling the dies 208, 210 and FIG. 5B may represent an opto-electronic assembly 500 subsequent to coupling the dies 208, 210. Techniques to electrically, optically, and/or mechanically couple the dies 208, 210 in FIGS. 5A-5B may comport with techniques described in connection with FIGS. 2A and 2B, except where otherwise indicated. FIGS. 5A-5B may depict the opto-electronic assembly 500 from a similar side view as the opto-electronic assembly 200 of FIG. 3 (e.g., arrow 333 providing a common reference direction in the Figures).

The first optical material 222 may have a height H1 relative to the surface S1 of the first die 208 and the second optical material may have a height H2 relative to the surface S2 of the second die 210. In some embodiments, one of the height H1 or the height H2 may be configured to define a gap distance, G, between the surface of the first semiconductor. In the depicted embodiment, the height H2 of the second optical material 226 defines the gap distance G. That is, height H2 may be equal to or substantially equal to the gap distance G. In this regard, height H2 may wholly define the gap distance G without the height H1. In other embodiments (not shown), the height H1 may wholly define the gap distance G without the height H2 (e.g., G=H1).

The dies 208, 210 may be coupled together using interconnect structures (e.g., interconnect structures 234 of FIGS. 2A-2B) as described in connection with FIGS. 2A-2B. That is, the dies 208, 210 may be positioned, aligned, and bonded (e.g., mechanically, electrically, and optically) using similar techniques as described in connection with FIGS. 2A-2B including a solder self-alignment process during solder reflow. The gap distance G may be configured to allow evanescent coupling between the waveguides 220, 224 through the optical materials 222, 226, and to allow passive alignment during solder reflow.

The dies 208, 210 may be positioned by fabrication equipment in FIG. 5A to provide a distance, W, between the optical materials 222, 226 after coupling the dies 208, 210, as can be seen in FIG. 5B. The distance W may physically separate the optical materials 222, 226 from one another in the direction of arrow 333 to allow space for movement of the dies 208, 210 relative to one another during passive alignment. Optical coupling efficiency may decrease as the distance W increases. In some embodiments, the distance W may be less than 10 microns. The distance W may have other values in other embodiments.

Subsequent to coupling of the dies 208, 210, light 105 can be routed from a light source 340 through the first waveguide 220 into the first optical material 222. The light 105 may expand or otherwise propagate through the first optical material 222 across the physical gap defined by the distance W and through the second optical material 226 (e.g., intensity at 388). The light 105 (e.g., intensity at 388) is received by the second waveguide 224, routed along the elongate dimension of the second waveguide 224 and output as light 107.

The optical materials 222, 226 may be configured side-by-side in the opto-electronic assembly 500 instead of over-and-under as depicted in the opto-electronic assembly 200. That is, in FIG. 5B, an optical interface 555 between surfaces of the optical materials 222, 226 may be perpendicular to the elongate dimension of the waveguides 220, 224 while in FIG. 3, an optical interface (e.g., region where surfaces of optical materials 222, 226 are in intimate contact) between surfaces of the optical materials 222, 226 may be parallel to the elongate dimension of the waveguides 220, 224. In some embodiments, the configuration of the first optical material 222 relative to the second optical material 226 may be referred to as “butt-coupling” to provide the optical interface 555 as described.

The optical pathway 400 may have a length, L, of about 1.5 millimeters (mm) or less, in some embodiments. The length, L, may extend in a direction (e.g., indicated by arrow 333) that is parallel with an elongate dimension of the waveguides 220, 224. The optical pathway 400 may have other dimensions in other embodiments.

FIG. 6 schematically illustrates a top perspective view of the optical coupling technique and configuration of FIG. 5B, in accordance with some embodiments. An optical pathway 600 is depicted on a three-coordinate axis where the x-axis is parallel with the arrow 333 of FIG. 5B, the y-axis is parallel with the arrow 272 of FIG. 2B, and the z-axis is perpendicular to a plane defined by the x-axis and the y-axis. The dies 208, 210 are not depicted for the sake of clarity.

The optical pathway 600 includes the first waveguide 220, the first optical material 222, the second optical material 226, and the second waveguide 224, optically coupled as shown to route light (e.g., light 105 of FIG. 5B) across an optical interface (e.g., optical interface 555 of FIG. 5B) of the optical materials 222, 226 (e.g., intensity illustrated by 388 of FIG. 5B) of the light by evanescent coupling. A portion of the second waveguide 224 is depicted in dashed form to indicate that the portion underlies the second optical material 226. In some embodiments, the waveguides 220, 224 and optical materials 222, 226 may have a tapered profile as shown to facilitate the routing of light through the optical pathway 400. The waveguides 220, 224 and optical materials 222, 226 may have other configurations and/or profiles in other embodiments.

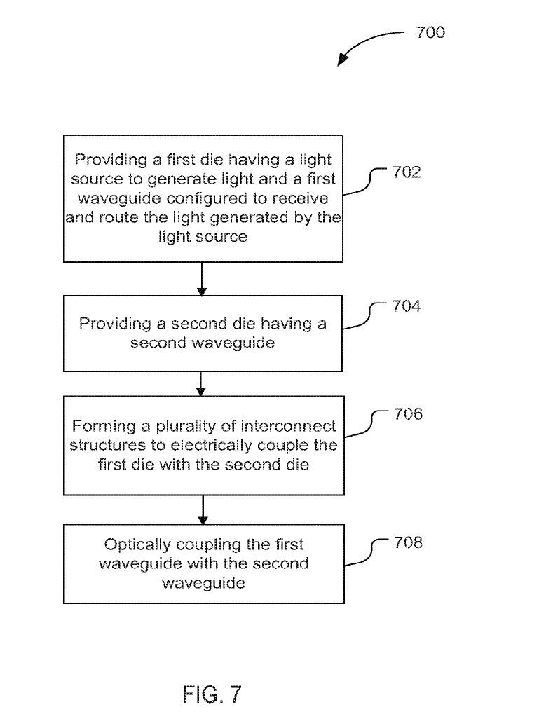

FIG. 7 is a flow diagram for a method 700 of fabricating an opto-electronic assembly (e.g., opto-electronic assembly 200 or opto-electronic assembly 500), in accordance with some embodiments. The method 700 may comport with techniques and configurations described in connection with FIGS. 1-6.

At 702, the method 700 includes providing a first die (e.g., first die 208) having a light source (e.g., light source 340) to generate light (e.g., light 105) and a first waveguide (e.g., first waveguide 220) configured to receive and route the light generated by the light source. At 704, the method 700 may further include providing a second die (e.g., second die 210) having a second waveguide (e.g., second waveguide 224). A first optical material (e.g., first optical material 222) may be disposed on the first waveguide and a second optical material (e.g., second optical material 226) may be disposed on the second waveguide.

At 706, the method 700 may further include forming a plurality of interconnect structures (e.g., interconnect structures 234) to electrically couple the first die with the second die. The interconnect structures can be formed by depositing an electrically conductive material such as, for example, copper or other metal to form structures (e.g., bumps 228 or pads 230) that are configured to electrically interconnect the dies. The interconnect structures can further be formed by depositing a solderable material (e.g., solderable material 232) and reflowing the solderable material to form electrical and/or mechanical bonds between the dies.

At 708, the method 700 may further include optically coupling the first waveguide with the second waveguide. In some embodiments, the surfaces of the dies may be positioned opposite one another and brought together until the first optical material and the second optical material make contact to define the gap distance G between the dies. In other embodiments, the surfaces of the dies may be brought together until the first optical material makes contact with the surface of the second die or the second optical material makes contact with the surface of the first die to define the gap distance G between the dies.

As further described in connection with FIGS. 2A-2B and FIGS. 5A-5B, actions associated with forming a plurality of interconnect structures to electrically couple the dies and actions associated with optically coupling the waveguides of the dies may be simultaneously performed. For example, a solder reflow process or thermocompression bonding (TCB) process may be used to simultaneously reflow the solderable material to form a mechanical and electrical connection between the dies, passively align the dies and waveguides relative to one another, and optically couple the waveguides through the optical materials. One or both of the optical materials may define the gap distance (e.g., gap distance G) between the dies to allow the optical coupling and passive alignment as described herein.

The actions of method 700 including fabrication of the dies, waveguides, and optical materials may be performed using techniques and materials that are compatible with high-volume manufacture and/or three-dimensional (3D) assembly.

Embodiments of the present disclosure may be implemented into a system using any suitable hardware and/or software to configure as desired. FIG. 8 schematically illustrates an example system (e.g., first or second processor-based system 125, 150 of FIG. 1) that may be part of an optical interconnect system (e.g., optical interconnect system 100 of FIG. 1) described herein in accordance with some embodiments. In one embodiment, the system 800 includes one or more processor(s) 804. One of the one or more processor(s) 804 may correspond, for example, with the processor 102 of FIG. 1.

The system 800 may further include system control module 808 coupled to at least one of the processor(s) 804, system memory 812 coupled to system control module 808, non-volatile memory (NVM)/storage 816 coupled to system control module 808, and one or more communications interface(s) 820 coupled to system control module 808.

System control module 808 for one embodiment may include any suitable interface controllers to provide for any suitable interface to at least one of the processor(s) 804 and/or to any suitable device or component in communication with system control module 808.

System control module 808 may include a memory controller module 810 to provide an interface to system memory 812. The memory controller module 810 may be a hardware module, a software module, and/or a firmware module.

System memory 812 may be used to load and store data and/or instructions, for example, for system 800. System memory 812 for one embodiment may include any suitable volatile memory, such as suitable Dynamic Random Access Memory (DRAM), for example.

System control module 808 for one embodiment may include one or more input/output (I/O) controller(s) to provide an interface to NVM/storage 816 and communications interface(s) 820.

The NVM/storage 816 may be used to store data and/or instructions, for example. NVM/storage 816 may include any suitable non-volatile memory, such as Phase Change Memory (PCM) or flash memory, for example, and/or may include any suitable non-volatile storage device(s), such as one or more hard disk drive(s) (HDD(s)), one or more compact disc (CD) drive(s), and/or one or more digital versatile disc (DVD) drive(s), for example.

The NVM/storage 816 may include a storage resource physically part of a device on which the system 800 is installed or it may be accessible by, but not necessarily a part of, the device. For example, the NVM/storage 816 may be accessed over a network via the communications interface(s) 820.

Communications interface(s) 820 may provide an interface for system 800 to communicate over one or more wired or wireless network(s) and/or with any other suitable device. For example, in some embodiments, the communication interface(s) 820 may be configured to communicate wirelessly over a wireless link established with a base station of a wireless communication network (e.g., radio access network (RAN) and/or core network). The communication interface(s) 820 may be configured with a transmitter, receiver, or transceiver to wirelessly transmit/receive signals according to various communication protocols including, for example, broadband wireless access (BWA) networks including networks operating in conformance with one or more protocols specified by the 3^{rd} Generation Partnership Project (3GPP) and its derivatives, the WiMAX Forum, the Institute for Electrical and Electronic Engineers (IEEE) 802.16 standards (e.g., IEEE 802.16-2005 Amendment), long-term evolution (LTE) project along with any amendments, updates, and/or revisions (e.g., advanced LTE project, ultra mobile broadband (UMB) project (also referred to as “3GPP2”), etc.). The communication interface(s) 820 may be configured to communicate using additional/alternative communication standards, specifications, and/or protocols. For example, the communication interface(s) 820 may be configured to communicate with wireless local area networks (WLANs), wireless personal area networks (WPANs) and/or wireless wide area networks (WWANs) such as cellular networks (e.g., 2G, 3G, 4G, etc.) and the like.

For one embodiment, at least one of the processor(s) 804 may be packaged together with logic for one or more controller(s) of system control module 808, e.g., memory controller module 810. For one embodiment, at least one of the processor(s) 804 may be packaged together with logic for one or more controllers of system control module 808 to form a System in Package (SiP). For one embodiment, at least one of the processor(s) 804 may be integrated on the same die with logic for one or more controller(s) of system control module 808. For one embodiment, at least one of the processor(s) 804 may be integrated on the same die with logic for one or more controller(s) of system control module 808 to form a System on Chip (SoC).

In various embodiments, the system 800 may be, but is not limited to, a server, a workstation, a desktop computing device, or a mobile computing device (e.g., a laptop computing device, a handheld computing device, a handset, a tablet, a smartphone, a netbook, ultrabook, etc.). In various embodiments, the system 800 may have more or less components, and/or different architectures. For example, in some embodiments, the system 800 may include one or more of a camera, a keyboard, display such as a liquid crystal display (LCD) screen (including touch screen displays), non-volatile memory port, antenna or multiple antennas, graphics chip, application-specific integrated circuit (ASIC), and speaker(s). In various embodiments, the system 800 may have more or less components, and/or different architectures.

The present disclosure may describe optical coupling techniques and configurations between dies of an opto-electronic assembly. In some embodiments, an opto-electronic assembly comprises a first semiconductor die including a light source to generate light, and a first mode expander structure comprising a first optical material disposed on a surface of the first semiconductor die, the first optical material being optically transparent at a wavelength of the light. The opto-electronic assembly may further comprise a second semiconductor die including a second mode expander structure comprising a second optical material disposed on a surface of the second semiconductor die, the second material being optically transparent at the wavelength of the light, wherein the second optical material is evanescently coupled with the first optical material to receive the light from the first optical material.

In some embodiments of the opto-electronic assembly, the first mode expander structure has a first height relative to the surface of the first die and the second mode expander structure has a second height relative to the surface of the second die a surface of the first mode expander structure is in direct contact with a surface of the second mode expander structure such that the first height and the second height define a gap distance between the surface of the first semiconductor die and the surface of the second semiconductor die, the gap distance being configured to allow the evanescent coupling of the first mode expander structure with the second mode expander structure. In some embodiments of the opto-electronic assembly, the surface of the first mode expander structure is substantially parallel with the surface of the first semiconductor die, the surface of the second mode expander structure is substantially parallel with the surface of the second semiconductor die and the gap distance is less than or equal to 8 microns.

In some embodiments, the opto-electronic assembly may further comprise a plurality of solder interconnect structures disposed between and electrically coupling the first semiconductor die and the second semiconductor die, wherein the first mode expander structure and the second mode expander structure are further configured to serve as a mechanical hard stop to define the gap distance between the first semiconductor die and the second semiconductor die during a solder self-alignment process that is used to form the plurality of solder interconnect structures.

In some embodiments of the opto-electronic assembly, the first optical material and the second optical material comprise a polymer having a Young's modulus in the range of 200 to 500 megapascals (MPa), the first waveguide and the second waveguide comprise silicon nitride (SiN), and the first optical material and the second optical material have an index of refraction from 1.5 to 2.

In some embodiments the opto-electronic assembly further comprises a first waveguide disposed on the surface of the first die, the first waveguide being configured to receive the light from the light source, and a second waveguide disposed on the surface of the second semiconductor die, wherein the first optical material is disposed on the first waveguide, wherein the second optical material is disposed on the second waveguide, and wherein the second waveguide is evanescently coupled with the first waveguide to receive the light from the first waveguide through the first optical material and the second optical material. In some embodiments of the opto-electronic assembly, the first optical material is configured to cover only a portion of the first waveguide and the second optical material is configured to cover only a portion of the second waveguide. In some embodiments of the opto-electronic assembly, the light source is a laser and the second semiconductor die is a photonic die, comprising at least one of a modulator or detector.

The present disclosure may further describe an opto-electronic assembly comprising a first semiconductor die including a light source to generate light, a first waveguide on a surface of the first die, the first waveguide being configured to route light, and a first optical material disposed on the first waveguide, the first optical material being optically transparent at a wavelength of the light and a second semiconductor die including a second waveguide on a surface of the second semiconductor die, and a second optical material disposed on the second waveguide, the second material being optically transparent at the wavelength of the light, wherein the second waveguide is optically coupled with the first waveguide to receive the light from the first waveguide through the first optical material and the second optical material, the first optical material being butt-coupled with the second optical material.

In some embodiments of the opto-electronic assembly, the first optical material has a first height relative to the surface of the first die and the second optical material has a second height relative to the surface of the second die and the first height or the second height is configured to define a gap distance between the surface of the first semiconductor die and the surface of the second semiconductor die during an assembly process that is used to form an electrical and mechanical bond between the first semiconductor die and the second semiconductor die, the gap distance further allowing the optical coupling of the second waveguide with the first waveguide. In some embodiments of the opto-electronic assembly, the first optical material and the second optical material are not in direct physical contact.

The present disclosure may further describe an apparatus comprising a waveguide disposed on a surface of a photonic die and an optical material disposed on the waveguide, wherein the waveguide is configured to evanescently couple with another waveguide disposed on a light-source die through the optical material, the optical material being optically transparent at a wavelength of light from the light-source die. In some embodiments of the apparatus, the photonic die further comprises a planar lightwave circuit (PLC) and at least one of one of a modulator, detector, splitter, or grating.

In some embodiments, the apparatus further comprises a plurality of solder interconnect structures formed on the surface of the photonic die, wherein the waveguide is disposed between at least two of the plurality of solder interconnect structures. In some embodiments of the apparatus, the optical material has a height relative to the surface of the photonic die that is configured to define, at least in part, a gap distance between the photonic die and the laser die, the gap distance being configured to allow the evanescent coupling of the waveguide with the another waveguide. In some embodiments of the apparatus, the optical material has a height that is configured to wholly define the gap distance between the photonic die and the light-source die.

The present disclosure further describes a system comprising a display a processor coupled with the display and an opto-electronic assembly being coupled with the processor, the opto-electronic assembly being configured to convert electrical signals of the processor to optical signals, the opto-electronic assembly including a first semiconductor die including a light source to generate light a first waveguide on a surface of the first die, the first waveguide being configured to receive and route the light generated by the light source, and a first optical material disposed on the first waveguide, the first optical material being optically transparent at a wavelength of the light and a second semiconductor die including a second waveguide on a surface of the second semiconductor die and a second optical material disposed on the second waveguide, the second material being optically transparent at the wavelength of the light, wherein the second waveguide is evanescently coupled with the first waveguide to receive the light from the first waveguide through the first optical material and the second optical material.

In some embodiments of the system, the first optical material has a first height relative to the surface of the first die and the second optical material has a second height relative to the surface of the second die and a surface of the first optical material is in direct contact with a surface of the second optical material such that the first height and the second height define a gap distance between the surface of the first semiconductor die and the surface of the second semiconductor die, the gap distance being configured to allow the evanescent coupling of the first waveguide with the second waveguide. In some embodiments, the system further comprises a plurality of solder interconnect structures disposed between and electrically coupling the first semiconductor die and the second semiconductor die, wherein the plurality of solder interconnect structures are configured to route the electrical signals of the processor and wherein the first optical material and the second optical material are configured to serve as a mechanical hard stop to define the gap distance between the first semiconductor die and the second semiconductor die during a solder self-alignment process that is used to form the plurality of solder interconnect structures.

In some embodiments of the system, the first semiconductor die is a laser die that is configured to generate the light using a laser light source and the second semiconductor die is a photonic die comprising a modulator and a detector. In some embodiments of the system, the first optical material has a first height relative to the surface of the first die and the second optical material has a second height relative to the surface of the second die and the first height or the second height is configured to define a gap distance between the surface of the first semiconductor die and the surface of the second semiconductor die, the gap distance being configured to allow the evanescent coupling of the first waveguide with the second waveguide.

In some embodiments of the system, the system further comprises a communication interface coupled with the processor to communicatively couple the system to a wireless network and the system is one of a server, a workstation, a desktop computing device, a tablet computing device, or a mobile computing device. In some embodiments of the system, the processor is a first processor of a first processor-based system and the opto-electronic assembly is a first opto-electronic assembly of the first processor-based system, the system further comprising a second processor-based system including a second processor and a second opto-electronic assembly coupled with the second processor, the second opto-electronic assembly being configured to convert electrical signals of the second processor to optical signals, wherein the second opto-electronic assembly is optically coupled with the first opto-electronic assembly to route the optical signals of the second processor to the first opto-electronic assembly or to route the optical signals of the first processor to the second opto-electronic assembly.

The present disclosure further describes a method of fabricating an opto-electronic assembly, the method comprising providing a first semiconductor die, the first semiconductor die including a light source to generate light, a first waveguide on a surface of the first die, the first waveguide being configured to receive and route the light generated by the light source, and a first optical material disposed on the first waveguide, the first optical material being optically transparent at a wavelength of the light, providing a second semiconductor die, the second semiconductor die including a second waveguide on a surface of the second semiconductor die and a second optical material disposed on the second waveguide, the second optical material being optically transparent at the wavelength of the light, wherein the second waveguide is evanescently coupled with the first waveguide to receive the light from the first waveguide through the first optical material and the second optical material, and optically coupling the first waveguide with the second waveguide such that the second waveguide is configured to receive the light from the first waveguide through the first optical material and the second optical material.

In some embodiments of the method, optically coupling the first waveguide with the second waveguide comprises evanescently coupling the first waveguide with the second waveguide. In some embodiments of the method, evanescently coupling the first waveguide with the second waveguide is performed by bringing the surface of the first semiconductor die and the surface of the second semiconductor die together such that the first optical material and the second optical material are in direct contact and define a gap distance between the first semiconductor die and the second semiconductor die, the gap distance being configured to allow the evanescent coupling of the first waveguide with the second waveguide. In some embodiments of the method, evanescently coupling the first waveguide with the second waveguide is performed by forming a plurality of solder interconnect structures to couple the first semiconductor die with the second semiconductor die using a solder reflow process that allows passive self-alignment of the first waveguide relative to the second waveguide, wherein the gap distance is configured to allow the passive self-alignment. In some embodiments of the method, the passive self-alignment provides less than 3 microns of misalignment of the first waveguide relative to the second waveguide in a direction that is substantially perpendicular to an elongate dimension of the first waveguide and the second waveguide. The first semiconductor die may be a laser die and the second semiconductor die may be a photonic die comprising at least one of a modulator or detector.

In some embodiments of the method, optically coupling the first waveguide with the second waveguide includes butt-coupling the first optical material with the second optical material, the first optical material has a first height relative to the surface of the first die and the second optical material has a second height relative to the surface of the second die, and the first height or the second height is configured to define a gap distance between the surface of the first semiconductor die and the surface of the second semiconductor die, the gap distance being configured to facilitate the optical coupling of the first waveguide with the second waveguide.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims and the equivalents thereof.

1. An opto-electronic assembly comprising:
a first semiconductor die including:
a light source to generate light, and
a first mode expander structure comprising a first optical material disposed on a surface of the first semiconductor die, the first optical material being optically transparent at a wavelength of the light; and
a second semiconductor die including:
a second mode expander structure comprising a second optical material disposed on a surface of the second semiconductor die, the second material being optically transparent at the wavelength of the light, wherein the second optical material is evanescently coupled with the first optical material to receive the light from the first optical material.

2. The opto-electronic assembly of claim 1, wherein:
the first mode expander structure has a first height relative to the surface of the first die and the second mode expander structure has a second height relative to the surface of the second die; and
a surface of the first mode expander structure is in direct contact with a surface of the second mode expander structure such that the first height and the second height define a gap distance between the surface of the first semiconductor die and the surface of the second semiconductor die, the gap distance being configured to allow the evanescent coupling of the first mode expander structure with the second mode expander structure.

3. The opto-electronic assembly of claim 2, wherein:
the surface of the first mode expander structure is substantially parallel with the surface of the first semiconductor die;
the surface of the second mode expander structure is substantially parallel with the surface of the second semiconductor die; and
the gap distance is less than or equal to 8 microns.

4. The opto-electronic assembly of claim 2, further comprising:
a plurality of solder interconnect structures disposed between and electrically coupling the first semiconductor die and the second semiconductor die, wherein the first mode expander structure and the second mode expander structure are further configured to serve as a mechanical hard stop to define the gap distance between the first semiconductor die and the second semiconductor die during a solder self-alignment process that is used to form the plurality of solder interconnect structures, wherein the first optical material and the second optical material comprise a polymer having a Young's modulus in the range of 200 to 500 megapascals (MPa);
the first waveguide and the second waveguide comprise silicon nitride (SiN); and
the first optical material and the second optical material have an index of refraction from 1.5 to 2.

5. (canceled)

6. The opto-electronic assembly of claim 1, further comprising:
a first waveguide disposed on the surface of the first die, the first waveguide being configured to receive the light from the light source; and
a second waveguide disposed on the surface of the second semiconductor die,
wherein the first optical material is disposed on the first waveguide,
wherein the second optical material is disposed on the second waveguide, and
wherein the second waveguide is evanescently coupled with the first waveguide to receive the light from the first waveguide through the first optical material and the second optical material, wherein the first optical material is configured to cover only a portion of the first waveguide; and
the second optical material is configured to cover only a portion of the second waveguide.

7. (canceled)

8. The opto-electronic assembly of claim 1, wherein:
the light source is a laser; and
the second semiconductor die is a photonic die, comprising at least one of a modulator or detector.

9. An opto-electronic assembly comprising:
a first semiconductor die including:
a light source to generate light,
a first waveguide on a surface of the first die, the first waveguide being configured to route light, and
a first optical material disposed on the first waveguide, the first optical material being optically transparent at a wavelength of the light; and
a second semiconductor die including:
a second waveguide on a surface of the second semiconductor die, and
a second optical material disposed on the second waveguide, the second material being optically transparent at the wavelength of the light, wherein the second waveguide is optically coupled with the first waveguide to receive the light from the first waveguide through the first optical material and the second optical material, the first optical material being butt-coupled with the second optical material.

10. The opto-electronic assembly of claim 9, wherein:
the first optical material has a first height relative to the surface of the first die and the second optical material has a second height relative to the surface of the second die; and
the first height or the second height is configured to define a gap distance between the surface of the first semiconductor die and the surface of the second semiconductor die during an assembly process that is used to form an electrical and mechanical bond between the first semiconductor die and the second semiconductor die, the gap distance further allowing the optical coupling of the second waveguide with the first waveguide, wherein the first optical material and the second optical material are not in direct physical contact.

11. (canceled)

12. An apparatus comprising:
a waveguide disposed on a surface of a photonic die; and
an optical material disposed on the waveguide, wherein the waveguide is configured to evanescently couple with another waveguide disposed on a light-source die through the optical material, the optical material being optically transparent at a wavelength of light from the light-source die.

13. The apparatus of claim 12, wherein the photonic die further comprises:
a planar lightwave circuit (PLC); and
at least one of one of a modulator, detector, splitter, or grating.

14. The apparatus of claim 12, further comprising:
a plurality of solder interconnect structures formed on the surface of the photonic die, wherein the waveguide is disposed between at least two of the plurality of solder interconnect structures.

15. The apparatus of claim 12, wherein the optical material has a height relative to the surface of the photonic die that is configured to define, at least in part, a gap distance between the photonic die and the laser die, the gap distance being configured to allow the evanescent coupling of the waveguide with the another waveguide.

16. The apparatus of claim 12, wherein the optical material has a height that is configured to wholly define the gap distance between the photonic die and the light-source die.

17. A system comprising:
a display;
a processor coupled with the display; and
an opto-electronic assembly being coupled with the processor, the opto-electronic assembly being configured to convert electrical signals of the processor to optical signals, the opto-electronic assembly including:
a first semiconductor die including:
a light source to generate light;
a first waveguide on a surface of the first die, the first waveguide being configured to receive and route the light generated by the light source; and
a first optical material disposed on the first waveguide, the first optical material being optically transparent at a wavelength of the light; and
a second semiconductor die including:
a second waveguide on a surface of the second semiconductor die; and
a second optical material disposed on the second waveguide, the second material being optically transparent at the wavelength of the light, wherein the second waveguide is evanescently coupled with the first waveguide to receive the light from the first waveguide through the first optical material and the second optical material.

18. The system of claim 17, wherein:
the first optical material has a first height relative to the surface of the first die and the second optical material has a second height relative to the surface of the second die; and
a surface of the first optical material is in direct contact with a surface of the second optical material such that the first height and the second height define a gap distance between the surface of the first semiconductor die and the surface of the second semiconductor die, the gap distance being configured to allow the evanescent coupling of the first waveguide with the second waveguide.

19. The system of claim 18, further comprising:
a plurality of solder interconnect structures disposed between and electrically coupling the first semiconductor die and the second semiconductor die, wherein the plurality of solder interconnect structures are configured to route the electrical signals of the processor and wherein the first optical material and the second optical material are configured to serve as a mechanical hard stop to define the gap distance between the first semiconductor die and the second semiconductor die during a solder self-alignment process that is used to form the plurality of solder interconnect structures wherein the first semiconductor die is a laser die that is configured to generate the light using a laser light source; and the second semiconductor die is a photonic die comprising a modulator and a detector.

20. (canceled)

21. The system of claim 17, wherein:
the first optical material has a first height relative to the surface of the first die and the second optical material has a second height relative to the surface of the second die; and
the first height or the second height is configured to define a gap distance between the surface of the first semiconductor die and the surface of the second semiconductor die, the gap distance being configured to allow the evanescent coupling of the first waveguide with the second waveguide.

22. The system of claim 17, wherein:
the system further comprises a communication interface coupled with the processor to communicatively couple the system to a wireless network; and
the system is one of a server, a workstation, a desktop computing device, a tablet computing device, or a mobile computing device.

23. The system of claim 17, wherein the processor is a first processor of a first processor-based system and the opto-electronic assembly is a first opto-electronic assembly of the first processor-based system, the system further comprising:
a second processor-based system including:
a second processor; and
a second opto-electronic assembly coupled with the second processor, the second opto-electronic assembly being configured to convert electrical signals of the second processor to optical signals, wherein the second opto-electronic assembly is optically coupled with the first opto-electronic assembly to route the optical signals of the second processor to the first opto-electronic assembly or to route the optical signals of the first processor to the second opto-electronic assembly.

24. A method of fabricating an opto-electronic assembly, the method comprising:
providing a first semiconductor die, the first semiconductor die including:
a light source to generate light;
a first waveguide on a surface of the first die, the first waveguide being configured to receive and route the light generated by the light source; and
a first optical material disposed on the first waveguide, the first optical material being optically transparent at a wavelength of the light;
providing a second semiconductor die, the second semiconductor die including:
a second waveguide on a surface of the second semiconductor die; and
a second optical material disposed on the second waveguide, the second optical material being optically transparent at the wavelength of the light, wherein the second waveguide is evanescently coupled with the first waveguide to receive the light from the first waveguide through the first optical material and the second optical material; and
optically coupling the first waveguide with the second waveguide such that the second waveguide is configured to receive the light from the first waveguide through the first optical material and the second optical material.

25. The method of claim 24, wherein optically coupling the first waveguide with the second waveguide comprises evanescently coupling the first waveguide with the second waveguide, wherein evanescently coupling the first waveguide with the second waveguide is performed by:
bringing the surface of the first semiconductor die and the surface of the second semiconductor die together such that the first optical material and the second optical material are in direct contact and define a gap distance between the first semiconductor die and the second semiconductor die, the gap distance being configured to allow the evanescent coupling of the first waveguide with the second waveguide.

26. (canceled)

27. The method of claim 25, wherein evanescently coupling the first waveguide with the second waveguide is performed by:
forming a plurality of solder interconnect structures to couple the first semiconductor die with the second semiconductor die using a solder reflow process that allows passive self-alignment of the first waveguide relative to the second waveguide, wherein the gap distance is configured to allow the passive self-alignment.

28. The method of claim 27, wherein the passive self-alignment provides less than 3 microns of misalignment of the first waveguide relative to the second waveguide in a direction that is substantially perpendicular to an elongate dimension of the first waveguide and the second waveguide.

29. The method of claim 24, wherein:
the first semiconductor die is a laser die; and
the second semiconductor die is a photonic die comprising at least one of a modulator or detector.

30. The method of claim 24, wherein:
optically coupling the first waveguide with the second waveguide includes butt-coupling the first optical material with the second optical material;
the first optical material has a first height relative to the surface of the first die and the second optical material has a second height relative to the surface of the second die; and
the first height or the second height is configured to define a gap distance between the surface of the first semiconductor die and the surface of the second semiconductor die, the gap distance being configured to facilitate the optical coupling of the first waveguide with the second waveguide.
